(19) United States
(12) Patent Application Publication
(10) Pub. No.: US 2011/0155229 A1
(43) Pub. Date: Jun. 30, 2011

(54) Solar cell and method for manufacturing the same

(75) Inventors: King Wai Lam, Tseung Kwan (HK); Wa-Sze Tsang, Wong Tai Sin (HK)

(73) Assignee: Du Pont Apollo Ltd.

(21) Appl. No.: 12/929,082

(22) Filed: Dec. 29, 2010

Related U.S. Application Data
(60) Provisional application No. 61/291,277, filed on Dec. 30, 2009.

(51) Int. Cl. H01L 31/105; H01L 31/18

(52) U.S. Cl. 136/255; 438/87; 257/E31.061

(57) ABSTRACT

A solar cell and a manufacturing method thereof have been disclosed in the present invention. According to the present invention, the p-layer or n-layer with the grooves helps to strengthen the electric filed of the solar cell and facilitates the carrier collection, thereby improving the overall efficiency of the solar cell.

### FIELD OF THE INVENTION

The present invention relates to a solar cell and a method for manufacturing the same. In particular, the solar cell has improved overall power output and overall efficiency.

### BACKGROUND OF THE INVENTION

Solar cells are being widely used in a variety of different applications. In space applications, for example, there is a need for light weight, low cost, but high efficiency solar cells. A typical solar cell includes a substrate, a front electrode, a photoelectric conversion element, and a back electrode disposed in order on the substrate. Incoming light is transmitted to the photoelectric conversion layer through the substrate and the front electrode, the photoelectric conversion element formed with a PIN or PN junction structure is to convert light energy into electric energy.

There has been a substantial research in solar cells. U.S. Pat. No. 4,500,744 discloses a photovoltaic device such as a solar cell, which comprises an amorphous silicon layer structure of a PIN type. The p-layer or n-layer on which light is incident can be comprised of a plurality of sub-layers. The sub-layer on the i-layer side has an optical forbidden band gap greater than that of the sub-layer on which light is incident, so that the solar cell can achieve an improved open circuit voltage, short circuit current density, and conversion efficiency. However, the sub-layers increase the distance between the p-layer and the n-layer and thus decrease the electric field and reduce the drift force. This will affect the collection of carriers and in turn limits cell efficiency.

U.S. Pat. No. 5,538,564 discloses a three dimensional amorphous silicon/microcrystalline silicon solar cell, which uses deep p and n contacts to create high electric fields within an active material of the cell. However, U.S. Pat. No. 5,538,564 does not address the contact problem between the p and n contacts with the active material (i.e., i-layer). The direct contact of the p and n contacts with the active material causes the possibility of the p+ and n+ carriers to diffuse into the active material. The presence of dopants in the active material reduces the light absorption capability of the active material, and thus reduces the overall power output and efficiency of the solar cell. Moreover, the p and n contacts are formed by pulsed laser doping. It is relatively difficult to control the profile of the contacts.

U.S. Pat. No. 6,261,862 discloses a process for producing a photovoltaic element. In the photovoltaic element of this type, the thickness of an i-layer has to be well controlled. If the i-layer is too thick, the electric field is weak, so as to affect the collection of carriers and limit cell efficiency. If the i-layer is too thin, the photovoltaic layer is insufficient to make an efficient solar cell. Moreover, buffering semiconductor layers are formed at the interface between the i-layer and the p-layer or i-layer to avoid the diffusion of dopants to the i-layer. Similarly, the added buffering semiconductor layers increase the distance between the p-layer and n-layer, and thus the electric field is even weaker than before.

In view of the above, there is a need for a higher efficiency solar cell. Such a need is provided by the present invention wherein the solar cell puts p- or n-contacts into the active material so that carriers can be picked up within the active material itself, rather than at the top and bottom of the active material layer, so as to produce a strong collecting field throughout the active material. Moreover, the contacts are provided by a patterning technique, so that the profile of the contacts can be well controlled and at least one buffer silicon layer can be deposited between the active material and the contacts to avoid the diffusion of dopants into the active material.

### SUMMARY OF THE INVENTION

It is an object of the present invention to provide a high efficiency solar cell.

According to the present invention, the solar cell comprises at least one first electrode, silicon layers in a PIN or NIP structure, and at least one second electrode, which are formed in sequence on an electrically insulating substrate, wherein the silicon layers comprise a p-layer, an i-layer, and a n-layer, which are formed in sequence or in reverse, and the p-layer or the n-layer, whichever is on the side of closer to the electrically insulating substrate with respect to the i-layer, has a plurality of grooves filled with the i-layer. The solar cell further comprises at least one buffer silicon layer formed between the i-layer and the p-layer or n-layer having the plurality of grooves.

Another object of the present invention is to provide a method for manufacturing the high efficiency solar cell.

According to the present invention, the manufacturing method comprises the steps of forming at least one first electrode, silicon layers in a PIN or NIP structure, and at least one second electrode in sequence on an electrically insulating substrate, wherein the silicon layers are made by forming a p-layer or a n-layer, using a patterning technique to form a plurality of grooves in the p-layer or n-layer, forming an i-layer on the p-layer or n-layer and covering the plurality of grooves, and forming a n-layer or p-layer on the i-layer. The method further comprises a step of forming at least one buffer silicon layer between the i-layer and the p-layer or n-layer having the plurality of grooves.

### BRIEF DESCRIPTION OF THE DRAWING

FIGS. 1(a) to 1(c) illustrate a method for manufacturing a solar cell according to one embodiment of the present invention.

FIG. 2 shows a schematic cross-sectional view of the solar cell according to another embodiment of the present invention.

### DETAILED DESCRIPTION OF THE INVENTION

A solar cell and a manufacturing method thereof have been disclosed in the present invention, wherein the methods and principles of photoelectric conversion used in the solar cell are well known to persons having ordinary skill in the art, and thus will not be further described hereafter.

For better understanding, the present invention is illustrated below in detail by the embodiments with reference to the drawings, which are not intended to limit the scope of the present invention. It will be apparent that any modifications or alterations that can easily be accomplished by those having ordinary skill in the art fall within the scope of the disclosure of the specification.

The electrically insulating substrate suitable for use in the present invention can be any substrate known to persons having ordinary skill in the art. For example, the substrate is composed of, but not limited to, glass, plastic, or metal.

The first electrode and second electrode suitable for use in the present invention are obvious to persons having ordinary skill in the art in view of different types of the solar cells, and can be made of any suitable materials, such as a transparent conductive oxide (TCO), a metal, and a combination thereof. The species of the transparent conductive oxide suitable for use in the present invention are known in the art, for example, but not limited to, tin oxide, indium oxide, zinc oxide, and indium tin oxide. The species of the metal suitable for use in the present invention are known in the art, for example, but not limited to, Al, Ag, Ti, Ni, Au, Cr, Pt, Zn, Mo, W, or an alloy thereof.

In the present invention, the electrode on which light is incident is called a front electrode and made of transparent conductive oxide, and the opposite electrode is called a back electrode and made of a metal or a combination of the transparent conductive oxide and metal. The electrode made of the transparent conductive oxide is formed by a suitable method such as resistance-heat vapor deposition, sputtering, spraying, screen printing, jet printing, and roll-to-roll processing, and the electrode made of the metal is formed by a suitable method such as vacuum vapor deposition, electron beam vapor deposition, sputtering, screen printing, jet printing, and roll-to-roll processing.

The i-layer of the silicon layers suitable for use in the present invention comprise amorphous silicon, amorphous silicon/microcrystalline silicon, crystalline silicon, and polycrystalline silicon, for example, but are not limited to, a-Si:H, a-Si:F, a-Si:H:F, a-SiC:H, a-SiC:F, a-SiC:H:F, a-SiGe:H, a-SiGe:F, a-SiGe:H:F, μc-SiH, μc-SiGe:H, μc-SiC:H, polycrystalline Si:H, polycrystalline Si:F, or polycrystalline Si:H:F (herein “a-” means “amorphous” and “μc-” means “microcrystalline”). The p-layer and n-layer may be formed by doping a valence electron-controlling agent into the same semiconductor material as the aforementioned one constituting the i-layer of the silicon layers.

In the present invention, the number of the buffer silicon layers formed between the i-layer and the p-layer or n-layer is not limited, and two is preferred. The buffer silicon layers suitable for use in the present invention are, for example, but are not limited to, a-Si:H, a-Si:F, a-Si:H:F, a-SiC:H, a-SiC:F, a-SiC:H:F, a-SiGe:H, a-SiGe:F, a-SiGe:H:F, μc-SiH, μc-SiGe:H, or μc-SiC:H.

The aforementioned respective silicon layers can be formed by a semiconductor film deposition process such as plasma enhanced chemical vapor deposition, photo-assisted chemical vapor deposition, thermal chemical vapor deposition, ion plating, and sputtering.

In the present invention, the grooves in the p-layer or n-layer are formed by conventional patterning techniques, for example, but not limited to, laser-scribing, electron gun, or photolithography, and laser-scribing is preferred. The depth of the plurality of the grooves ranges from about 200 Å to about 3000 Å, and preferably about 200 Å to about 1500 Å. The distance between two adjacent grooves ranges from about 0.1 μm to about 2 μm, and preferably about 0.2 μm to about 1.0 μm.

In an embodiment of the present invention, the plurality of grooves can divide the p-layer or n-layer into numbers of p-contacts or n-contacts. The depth of the contacts ranges from about 200 Å to about 3000 Å, and preferably about 200 Å to about 1500 Å. The width of the contacts ranges from about 0.1 μm to about 2 μm, and preferably about 0.2 μm to about 1.0 μm.

According to the preset invention, additional buffer silicon layers may be formed between the i-layer and the p-layer or the n-layer on the side of closer to the second electrode of the solar cell.

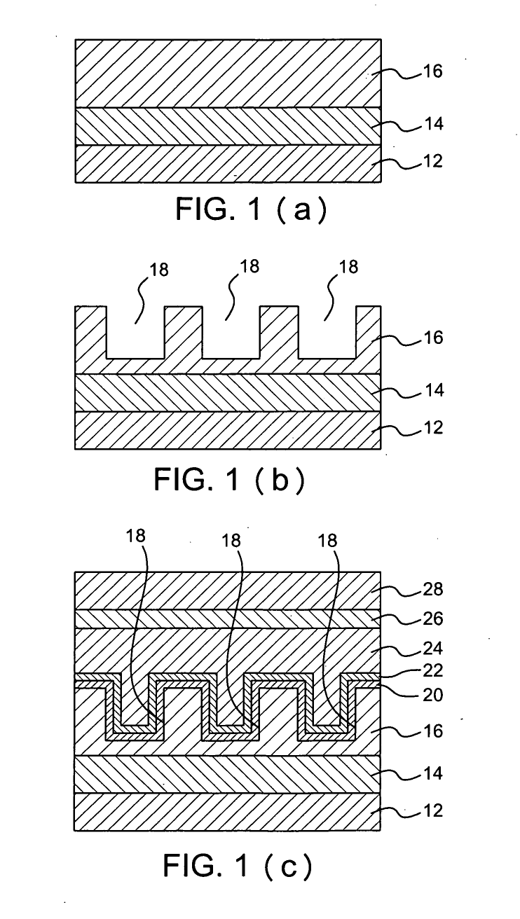

The preferred embodiments of the process for producing a solar cell of the present invention are explained by reference to annexed drawings. FIGS. 1(a) to 1(c) illustrate a method for manufacturing a solar cell according to one embodiment of the present invention.

As shown in FIG. 1(a), a transparent conductive oxide layer is deposited on a glass substrate 12 as a front electrode 14, and a p+ SiC layer 16 is deposited on the front electrode 14. As shown in FIG. 1(b), a laser-scribing process is used to form a plurality of grooves 18 in the p+ SiC layer 16. As shown in FIG. 1(c), a p-SiC layer 20 is deposited on the p+ SiC layer 16 and the grooves 18, and a SiC layer 22 is deposited on the p-SiC layer 20. After that, an i-layer 24 is deposited on the SiC layer 22 and fills the grooves 18, and a n-SiC layer 26 is deposited on the i-layer 24. Finally, a ZnO layer and patterned Ag/Ti layer are deposited on the n-SiC layer 26 as a back electrode 28.

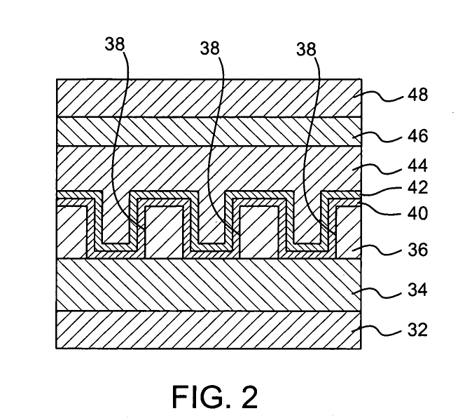

FIG. 2 shows a schematic cross-sectional view of the solar cell according to another embodiment of the present invention. As shown in FIG. 2, a front electrode 34 is deposited on a glass substrate 32, a plurality of p+ SiC contacts 36 are formed on the front electrode 34 by using a laser scribing process to define a plurality of grooves 38 in a p+ SiC layer (not shown), a p-SiC layer 40 and a SiC layer 42 are subsequently deposited on the p+ SiC contacts 36 and the grooves 38, an i-layer 44 is deposited on the SiC layer 42 and fills the grooves 38, and a n-SiC layer 46 and a back electrode 48 is deposited on the i-layer 44.

Given the above, the solar cell of the present invention uses p contacts or n contacts to create high electric fields within the i-layer of the cell. When the electric field is increased, the amount of carrier collection is increased. This in turn improves the efficiency of the solar cell. Moreover, when the electric field increases, the series resistance in the solar cell is reduced, and thus less power is dissipated as heat. In addition, the amount of degradation will be reduced when the electric field is stronger. The two effects mentioned above effectively improve the overall power output generated and the overall efficiency of the solar cell of the present invention.

Although the present invention has been described with reference to illustrative embodiments, it should be understand that any modifications or alterations that can easily be accomplished by persons skilled in the art will fall within the scope of the disclosure of the specification and the appended claims.

What is claimed is:

1. A solar cell comprising at least one first electrode, silicon layers in a PIN or NIP structure, and at least one second electrode, which are formed in sequence on an electrically insulating substrate,
wherein the silicon layers comprise a p-layer, an i-layer, and a n-layer, which are formed in sequence or in reverse, and the p-layer or the n-layer, whichever is on the side of closer to the electrically insulating substrate with respect to the i-layer, has a plurality of grooves filled with the i-layer.

2. The solar cell of claim 1, wherein the depth of the plurality of the grooves ranges from about 200 Å to about 3000 Å.

3. The solar cell of claim 1, wherein the distance between two adjacent grooves ranges from about 0.1 μm to about 2 μm.

4. The solar cell of claim 1, wherein the plurality of grooves divide the p-layer or n-layer into numbers of p-contacts or n-contacts.

5. The solar cell of claim 4, wherein the depth of the p-contacts or n-contacts ranges from about 200 Å to about 3000 Å.

6. The solar cell of claim 4, wherein the width of the p-contacts or n-contacts ranges from about 0.1 μm to about 2 μm.

7. The solar cell of claim 1 further comprising at least one buffer silicon layer formed between the i-layer and the p-layer or n-layer having the plurality of grooves.

8. A method for manufacturing a solar cell comprising forming at least one first electrode, silicon layers in a PIN or NIP structure, and at least one second electrode in sequence on an electrically insulating substrate,
wherein the silicon layers are made by forming a p-layer or a n-layer, using a patterning technique to form a plurality of grooves in the p-layer or n-layer, forming an i-layer on the p-layer or n-layer and covering the plurality of grooves, and forming a n-layer or p-layer on the i-layer.

9. The method of claim 8, wherein the patterning technique comprises laser-scribing, electron gun, or photolithography.

10. The method of claim 8, wherein the patterning technique is laser-scribing.

11. The method of claim 8, wherein the depth of the plurality of the grooves ranges from about 200 Å to about 3000 Å.

12. The method of claim 8, wherein the distance between two adjacent grooves ranges from about 0.1 μm to about 2 μm.

13. The method of claim 8, wherein the plurality of grooves are formed to divide the p-layer or n-layer into numbers of p-contacts or n-contacts.

14. The method of claim 13, wherein the depth of the p-contacts or n-contacts ranges from about 200 Å to about 3000 Å.

15. The method of claim 13, wherein the width of the p-contacts or n-contacts ranges from about 0.1 μm to about 2 μm.

16. The method of claim 8 further comprising a step of forming at least one buffer silicon layer between the i-layer and the p-layer or n-layer having the plurality of grooves.
